(19) United States
(12) Patent Application Publication
(10) Pub. No.: US 2025/0354291 A1
(43) Pub. Date: Nov. 20, 2025

(54) INHIBITORS FOR SELECTIVE EPITAXIAL DEPOSITION

(71) Applicant: Applied Materials, Inc., Santa Clara, CA (US)

(72) Inventors: Joe MARGETIS, Gilbert, AZ (US); John TOLLE, Gilbert, AZ (US); Orsy CRUZ, Santa Clara, CA (US)

(21) Appl. No.: 18/668,884

(22) Filed: May 20, 2024

(51) Int. Cl. C30B 25/04; C30B 25/16; C30B 25/18; C30B 29/06

(52) U.S. Cl. CPC C30B 25/04; C30B 25/165; C30B 25/186; C30B 29/06

(57) ABSTRACT

The present disclosure provides systems and methods of processing substrates. A surface of a substrate is exposed to an inhibitor. The surface of the substrate includes one or more dielectric regions and one or more semiconductor regions. The inhibitor includes a halogen-containing compound including tin. A silicon-containing material layer is epitaxially and selectively deposited on the substrate after exposing the surface of the substrate to the inhibitor.

### BACKGROUND

### Field

Embodiments of the present disclosure generally relate to processing chambers, and related methods and apparatus, for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. In some embodiments, selective deposition may be performed, where the material is grown only on the semiconductor surfaces of the substrate. This is typically achieved through the addition of an etchant gas such as HCl to the deposition chemistry.

Conventional approaches to selective deposition which use HCl gas become ineffective to due to the diminished reactivity of the etch gas at low temperature. Alternative etch gases, such as Cl₂, may be employed to recover the low temperature reactivity. However Cl₂ can only be used in very specific conditions and thus limits the application space. A third approach seeks to chemically deactivate the dielectric surface with the use of inhibitor molecules such that nucleation and growth is impeded. Inhibitors have been widely used in selective atomic layer deposition (ALD) and often these molecules consist of large organic molecules. However, inhibition during epitaxial deposition is complex because of the higher temperatures and partial pressures typically employed relative to ALD. Additionally, this class of inhibitors can cause unwanted deposition and/or unwanted carbon, oxygen, and/or nitrogen contamination.

Therefore, a need exists for improved apparatuses and methods in semiconductor processing.

### SUMMARY

In some embodiments, the present disclosure provides systems and methods of processing substrates. A surface of a substrate is exposed to an inhibitor. The surface of the substrate includes one or more dielectric regions and one or more semiconductor regions. The inhibitor includes a halogen-containing compound including tin. A silicon-containing material layer is epitaxially and selectively deposited on the substrate after exposing the surface of the substrate to the inhibitor.

In other embodiments, the present disclosure provides computer readable mediums. The computer readable mediums configured to expose a surface of a substrate to an inhibitor. The surface of the substrate includes one or more dielectric regions and one or more semiconductor regions. The inhibitor includes a halogen-containing compound including tin. A silicon-containing material layer is epitaxially and selectively deposited on the substrate after exposing the surface of the substrate to the inhibitor.

In other embodiments, the present disclosure provides processing systems. The processing systems include a processing chamber and a controller. The controller is configured to expose a surface of a substrate to an inhibitor. The surface of the substrate includes one or more dielectric regions and one or more semiconductor regions. The inhibitor includes a halogen-containing compound including tin. A silicon-containing material layer is epitaxially and selectively deposited on the substrate after exposing the surface of the substrate to the inhibitor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic side cross-sectional view of a processing chamber, according to embodiments of the disclosure.

FIG. 2 shows a process method, according to embodiments of the disclosure.

FIGS. 3A and 3B show a substrate corresponding to the method of FIG. 2, according to embodiments of the disclosure. FIG. 3A shows a substrate prior to a deposition process. FIG. 3B shows a substrate after a deposition process.

FIG. 4 shows a thickness vs time graph, according to embodiments of the disclosure.

FIGS. 5A and 5B show a secondary ion mass spectrometry spectra of a substrate surface pre-dosed with an inhibitor, according to embodiments of the disclosure. FIG. 5A shows spectra of a depth profile for an SiO₂ dosed surface with Si grown on top. FIG. 5B shows the depth profile of a dosed SiGe surface.

FIG. 6 shows an x-ray diffraction spectra of a substrate, according to embodiments of the disclosure.

FIGS. 7A-7F show an atomic force microscopy images comparing substrates with no inhibitor and substrates dosed with increasing amounts of the inhibition chemical, according to embodiments of the disclosure. FIG. 7A shows an image of a a control substrate. FIG. 7B shows an image of a control substrate. FIG. 7C shows an image of a substrate treated with a first inhibitor. FIG. 7D shows an image of a substrate treated with a first inhibitor. FIG. 7E shows an image of a substrate treated with a second inhibitor. FIG. 7F shows an image of a substrate treated with a second inhibitor.

FIGS. 8A-8C show an atomic force microscopy image of a substrate treated with varying flow rates of an inhibitor, according to embodiments of the disclosure. FIG. 8A shows a first flow rate of an inhibitor. FIG. 8B shows a second flow rate of an inhibitor. FIG. 8C shows a third flow rate of an inhibitor.

FIGS. 9A-9C show an atomic force microscopy image of a substrate treated with varying flow rates of an inhibitor, according to embodiments of the disclosure. FIG. 9A shows a first flow rate of an inhibitor. FIG. 9B shows a second flow rate of an inhibitor. FIG. 9C shows a third flow rate of an inhibitor.

FIGS. 10A-10C show an atomic force microscopy image of a substrate treated with an inhibitor according to cyclic pulsing, according to embodiments of the disclosure. FIG. 10A shows a first treatment method. FIG. 10B shows a second treatment method. FIG. 10C shows a third treatment method.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to processing chambers and related methods and apparatus, for semiconductor manufacturing.

### Processing Chamber

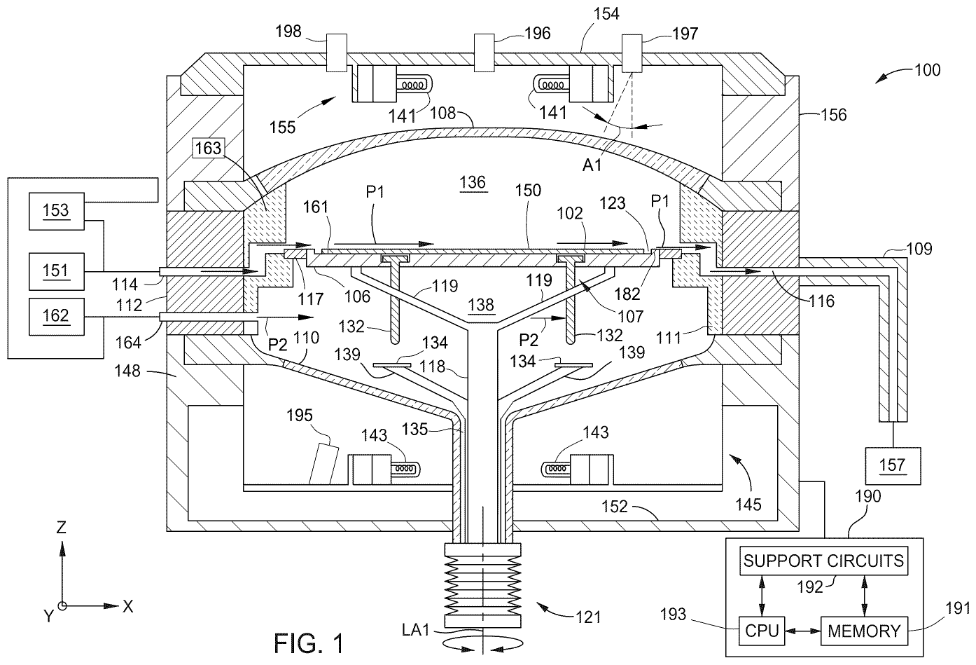

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of gases, e.g., precursors and/or inhibitors, across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), and one or more heat sources 141, 143. The one or more heat sources 141, 143 include a plurality of upper heat sources 141 and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper window 108 and the lower window 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper window and a lid 154. The plurality of upper heat sources 141 form a portion of the upper heat source module 155.

The plurality of lower heat sources 143 are disposed between the lower window 110 and a floor 152. The plurality of lower heat sources 143 form a portion of a lower heat source module 145. The upper window 108 is an upper dome and/or is formed of an energy transmissive material, such as quartz. The lower window 110 is a lower dome and/or is formed of an energy transmissive material, such as quartz.

A processing volume 136 and a purge volume 138 are formed between the upper window 108 and the lower window 110. The processing volume 136 and the purge volume 138 are part of an internal volume defined at least partially by the upper window 108, the lower window 110, and one or more liners 111, 163. In one or more embodiments, the processing volume 136 is a processing volume and/or an inhibitor volume. The one or more liners 111, 163 are disposed inwardly of the chamber body.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin openings 107 disposed therein. The lift pin openings 107 are each sized to accommodate a lift pin 132 for lifting of the substrate 102 from the substrate support 106 before or after a deposition process and/or a treatment process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more inlets 114 (e.g., a plurality of inlets), one or more purge gas inlets 164 (e.g., a plurality of purge gas inlets), and one or more exhaust outlets 116. In some embodiments, the one or more inlets 114 can include one or more gas inlets. In some embodiments, the one or more inlets 114 can include one or more liquid inlets. The one or more inlets 114 and the one or more purge gas inlets 164 are disposed on the opposite side of the flow module 112 from the one or more exhaust outlets 116. A pre-heat ring 117 is disposed below the one or more inlets 114 and the one or more exhaust outlets 116. The pre-heat ring 117 is disposed above the one or more purge gas inlets 164. The pre-heat ring 117 can include a complete ring or one or more ring segments. The one or more liners 111, 163 are disposed on an inner surface of the flow module 112 and protects the flow module 112 from reactive gases used during deposition operations, and/or treatment operations. The inlet(s) 114 and the purge gas inlet(s) 164 are each positioned to flow a respective one or more process gases P1, inhibitor gases and/or liquids, and one or more purge gases P2 parallel to the top surface 150 of a substrate 102 disposed within the processing volume 136. The inlet(s) 114 are fluidly connected to one or more process gas sources 151 and/or one or more inhibitor sources 153. The purge gas inlet(s) 164 are fluidly connected to one or more purge gas sources 162. The one or more exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more inhibitors supplied using the one or more inhibitor sources 153 can include one or more reactive liquids (such as one or more of halogen-containing compounds, e.g., tin tetrachloride, dichlorodimethylsilane, or a combination thereof), and/or one or more reactive gasses (such as chlorine, hydrogen, or a combination thereof). In one or more embodiments, the one or more process gases P1 include silicon phosphide (SiP) and/or phosphine (PH₃), and the one or more inhibitors can comprise tin tetrachloride. In one or more embodiments, the one or more process gases P1 include silicon phosphide (SiP) and/or phosphine (PH₃), and the one or more cleaners comprise dichlorodimethylsilane.

The one or more exhaust outlets 116 are further connected to or include an exhaust system 109. The exhaust system 109 fluidly connects the one or more exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more inlets 114 in fluid communication with the processing volume 136. The one or more inlets 114 are in fluid communication with one or more flow gaps between the upper liner 163 and a lower liner 111. The one or more second gas inlets (not shown) are in fluid communication with the one or more inlet openings (not shown) of the upper liner 163.

During a deposition operation (e.g., an epitaxial growth operation), the one or more process gases P1 flow through the one or more inlets 114, through the one or more gaps, and into the processing volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1 and/or the inhibitor gases and/or liquids. The one or more process gases P1 are exhausted through gaps between the upper liner 163 and the lower liner 111, and through the one or more exhaust outlets 116. The one or more inhibitor gases and/or liquids are exhausted through gaps between the upper liner 163 and the lower liner 111, and through the one or more exhaust outlets 116. The one or more purge gases P2 can be exhausted through one or more outlet openings, and through the same one or more exhaust outlets 116 as the one or more process gases P1 and/or inhibitor gases and/or liquids. The present disclosure contemplates that that the one or more purge gases P2 can be separately exhausted through one or more second gas exhaust outlets that are separate from the one or more exhaust outlets 116.

During a treatment operation, one or more inhibitor gases and/or liquids flow through the one or more inlets 114, through the one or more gaps (between the upper liner 163 and the lower liner 111), and into the processing volume 136.

The processing system includes one or more sensor devices 195, 196, 197, 198 (e.g., temperature sensors) configured to measure parameter(s) (e.g., temperature(s)) within the processing chamber 100. In one or more embodiments, the one or more temperature sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one or more embodiments, the one or more sensor devices 195, 196, 197, 198 each include a sensor that includes one or more of silicon (Si), carbon (C), gallium (Ga), and/or nitrogen (N). In one or more embodiments, the one or more sensor devices 195, 196, 197, 198 each include a silicon sensor, a silicon carbide (SiC) sensor, and/or a gallium nitride (GaN) sensor. In one or more embodiments, each sensor device 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature.

In one or more embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

Each sensor device 195, 196, 197, 198, can be a single-wavelength sensor device or a multi-wavelength (such as dual-wavelength) sensor device. In one or more embodiments, the system including the process chamber 100 includes any one, any two, or any three of the four illustrated sensor devices 195, 196, 197, 198. In one or more embodiments, the process chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198.

As shown, a controller 190 is in communication with the processing chamber 100 and is used to control processes and methods, such as the operations of the methods (e.g., the method 200) described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, the substrate support 106, and/or the liners 111, 163. As described the one or more sensor devices can include, for example pyrometers.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power applied to the heat sources 141, 143, a treatment recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations described herein (such as operation(s) of the method 200) to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control power to the heat sources 141, 143, the deposition, the treatment, the rotational position, the heating, and gas flow through the processing chamber 100 by providing an output to the controls for the sensor devices 195, 196, 197, 198, the upper heat sources 141, the lower heat sources 143, the process gas source 151, the purge gas source 162, the motion assembly 121, and/or the exhaust pump 157.

### Methods

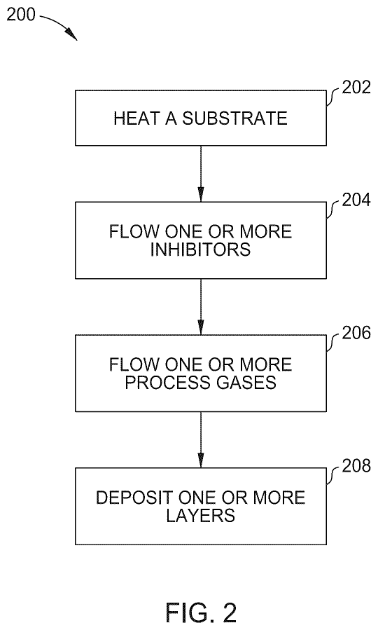

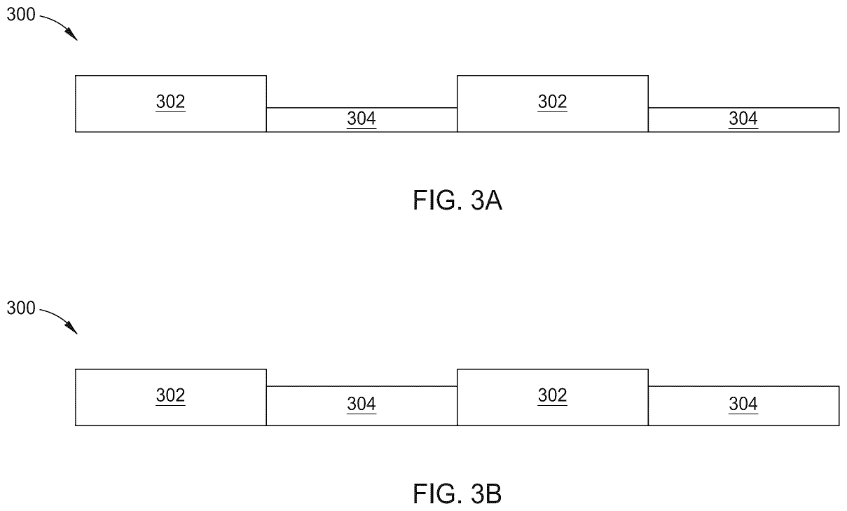

FIG. 2 is a schematic block diagram view of a method 200 of substrate 300 (As shown in FIGS. 3A and 3B) processing for semiconductor manufacturing, according to one or more embodiments.

Operation 202 of the method 200 includes heating a substrate positioned on a substrate support in a processing volume of a processing chamber. In one or more embodiments, the substrate is heated by a resistive heater in the substrate support to a target temperature. In at least one embodiment, the target temperature can include a temperature of less than 900° C., e.g., about 0° C. to about 100° C., about 100° C. to about 200° C., about 200° C. to about 300° C., about 300° C. to about 400° C., about 400° C. to about 500° C., about 500° C. to about 600° C., about 600° C. to about 700° C., about 700° C. to about 800° C., or about 800° C. to about 900° C. In an embodiment, heating the substrate can include exposing the substrate to a plasma pre-cleaning process. The plasma pre-cleaning process can include exposing the substrate to a plasma clean process, e.g., a process that utilizes plasma generated by NF₃ and/or NH₃ to remove one or more contaminants on a surface of the substrate. In an embodiment, the pre-cleaning process can convert and/or expose one or more surfaces of the substrate to a silicon oxide surface having one or more hydroxyl reactive sites.

Operation 204 includes flowing one or more inhibitors over the substrate 300 including a plurality of materials formed thereon, e.g., dielectric materials 302 and epitaxial materials 304, as shown in FIG. 3A. The one or more inhibitors can include one or more of halogen-containing compounds. The one or more halogen containing compounds can include a chlorine, bromine, iodine, astatine, tennessine, or a combination thereof. The one or more halogen containing compounds can include one or more metals, metal alloys, transition metals, rare earth metals, or a combination thereof. For example, the one or more halogen containing compounds can include one or more of Si, Zn, La, Pr, Nd, Sm, Eu, Gd, Tb, Dy, Ho, Er, Tm, Yb, Lu, Ce, Co, Y, Bi, Cd, Pb, Ag, Sb, Sn, Cu, Fe, Ni, Li, Ca, Sr, Mg, Zr, Nd, Ba, Sc, or any combination thereof. The one or more halogen containing compounds can include one or more metalloids. For example, the one or more metalloids can include boron, silica, germanium, arsenic, antimony, tellurium, or a combination thereof. The one or more halogen containing compounds can include one or more organic ligands, e.g., C₁-C₆ alkyl, C₁-C₆ alkylene, C₁-C₆ alkynl, C₁-C₆ alkynlene, or a combination thereof. In at least one embodiment, the one or more halogen containing compounds includes tetrachloride a tin based compound, e.g., SnCl₄, SnCl₂ (CH₃)₂, Sn(CH₃)₄, SnBr₄, SnBr₂ (CH₃)₂, and any combination thereof. For example, the one or more halogen containing compounds includes tin tetrachloride. As a further example, the one or more halogen containing compounds includes dichlorodimethylsilane.

In at least one embodiment, hydrochloric acid can be introduced concurrently with one or more additional halogen containing compounds. Without being bound by theory, the use of a halogen containing compound can slow the growth rate of the material on the dielectric surface with minimal impact to the epitaxial material growth rate. Additionally, and without being bound by theory, the use of a halogen containing compound can allow for selective epitaxial growth to be conducted at lower temperatures, e.g., temperature of less than 550° C.

In embodiment, the one or more inhibitors can include a binding ligand and an inhibition ligand. The binding ligand can bind to one or more reactive sites of the dielectric material and/or epitaxial material, e.g., a hydroxyl reactive site. The inhibition ligand may remain on the inhibitor that is bound to the dielectric material such that binding of the one or more process gases, described below, to the dielectric material is reduced. For example, an inhibitor comprising tin tetrachloride may react with a hydroxyl site of the dielectric material to release HCl gas and bind the tin-tetrachloride to the dielectric material. The remaining chlorides of the tin-chloride species may then act as the inhibition ligand, reducing the ability of the process gases to bind to the dielectric material.

The one or more inhibitors can be flowed at a volumetric flow rate of about 1 standard cubic centimeters per minute (sccm) to about 100 sccm, e.g., about 1 sccm to about 20 sccm, about 20 sccm to about 30 sccm, about 30 sccm to about 40 sccm, about 40 sccm to about 50 sccm, about 50 sccm to about 60 sccm, about 60 sccm to about 70 sccm, about 70 sccm to about 80 sccm, about 80 sccm to about 90 sccm, or about 90 sccm to about 100 sccm. Without being bound by theory, the volumetric flow rate may be about 1 sccm to about 100 sccm to provide sufficient inhibitors in the processing chamber to inhibit a reactive site of the dielectric material, e.g., a hydroxyl site. The one or more inhibitors may can be flowed into the processing chamber at a pressure of about 1 Torr to about 300 Torr, e.g., about 1 Torr to about 10 Torr, about 10 Torr to about 100 Torr, about 100 Torr to about 200 Torr, about 200 Torr to about 300 Torr, or about 300 Torr to about 400 Torr. Without being bound by theory, the use of a halogen containing compound can allow for selective epitaxial growth to be conducted at greater pressures.

The one or more inhibitors can be flowed for a period of time of about 0.1 seconds to about 60 seconds, e.g., about 0.1 seconds to about 10 seconds, about 10 seconds to about 20 seconds, about 20 seconds to about 30 seconds, about 30 seconds to about 40 seconds, about 40 seconds to about 50 seconds, or about 50 seconds to about 60 seconds. In an embodiment, the one or more inhibitors can be flowed in one or more intervals according to a cyclic pulsing method. For example, the cyclic pulsing method includes the inhibitor flowing for a set period of time, typically 5 to 10 seconds, before the desired process gas is introduced to the chamber. The epitaxial material growth can be halted, and the inhibitor flow can resume in order to allow more of the inhibitor to bind to the dielectric surface. This is repeated several times, until the desired growth target is achieved. Without being bound by theory, in the first cycle the inhibitor may bind to about 90 to about 99% of the reactive sites of the dielectric material, where a second inhibitor cycle may bind to the remaining reactive sites of the epitaxial material. Without being bound by theory, ease of automation and repeatability may be achieved by implementing similar lengths of the inhibitor cycles for each cycle. Without being bound by theory, cycling the inhibitor can replenish the surface, thereby preventing decomposition or desorption of the inhibitor during the deposition cycle. As a further example, the cyclic pulsing method can include flowing a first cycle of about 5 seconds, a second cycle of about 5 seconds, a third cycle of about 5 seconds, a fourth cycle of about 5 seconds, a fifth cycle of about 5 seconds, and a sixth cycle of about 5 seconds, in which the first cycle, second cycle, third cycle, fourth cycle, fifth cycle, and/or sixth cycle may be the same or different.

Operation 504 includes flowing one or more process gases over the substrate. The one or more process gases can include one or more reactive gases (such as one or more including silicon (Si), phosphorus (P), and/or germanium (Ge)) and/or one or more carrier gases (such as one or more of nitrogen (N₂) and/or hydrogen (H₂)). For example, the one or more process gases can include silane, phosphine, germanium hydride, diborane, or a combination thereof.

The one or more process gases can be flowed at a rate of about 10 standard cubic centimeters per minute (sccm) to about 100 sccm, e.g., about 10 sccm to about 20 sccm, about 20 sccm to about 30 sccm, about 30 sccm to about 40 sccm, about 40 sccm to about 50 sccm, about 50 sccm to about 60 sccm, about 60 sccm to about 70 sccm, about 70 sccm to about 80 sccm, about 80 sccm to about 90 sccm, or about 90 sccm to about 100 sccm. The one or more process gases may can be flowed into the processing chamber at a pressure of about 1 Torr to about 300 Torr, e.g., about 1 Torr to about 10 Torr, about 10 Torr to about 100 Torr, about 100 Torr to about 200 Torr, about 200 Torr to about 300 Torr, or about 300 Torr to about 400 Torr.

Operation 506 includes depositing one or more layers on the epitaxial material 304 of the substrate 300, as shown in FIG. 3B. The one or more layers can include a thickness of about 100 Å to about 300 Å, e.g., about 100 Å to about 150 Å, about 150 Å to about 200 Å, about 200 Å to about 250 Å, or about 250 Å to about 300 Å.

Overall, the present disclosure provides methods of selectively depositing a layer on a substrate by preventing nucleation on the dielectric material without inhibiting growth on the epitaxial material through the use of one or more inhibitors having an inhibition ligand and a binding ligand. The methods include using an inhibitor such that the selective deposition can be operated at lower temperatures, e.g., temperatures less than 550° C. By selectively depositing a layer on a substrate at lower temperatures, a reduction of processing costs occurs as well as an increase in the processability of the substrates. Additionally, by selectively depositing a layer on the substrate a reduction of contamination in the substrate may occur, increasing device performance.

### EXAMPLES

### Example 1

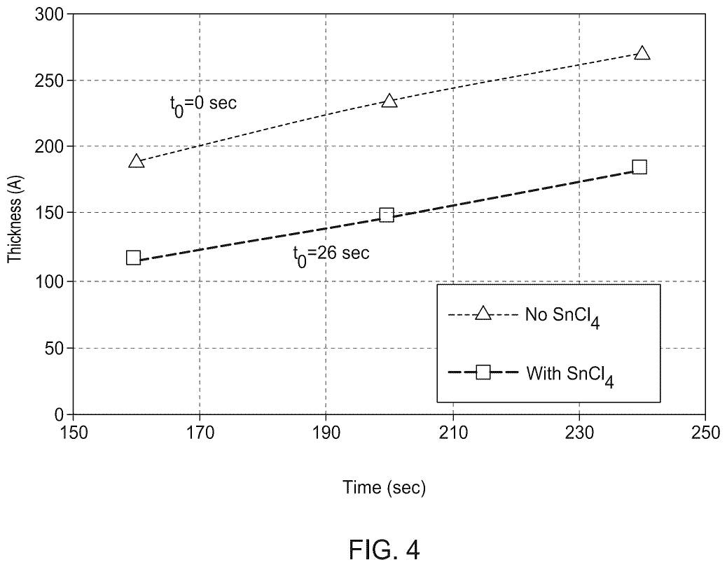

A SiO₂ substrate was compared to a substrate that was treated with a single dose of tin tetrachloride for 30 seconds, at a flow rate of about 5 sccm to about 100 sccm, prior to the deposition process. A pressure of 20 Torr, a temperature of 500° C. and a flow of 35 sccm of tin tetrachloride was utilized. By treating the substrate prior to the deposition process, the thickness of the epitaxial growth on the dielectric material was reduced by about 50 Å after about 160 seconds, as shown in FIG. 4. This reduction in thickness on the dielectric material allows for improved selectivity of epitaxial growth on epitaxial material.

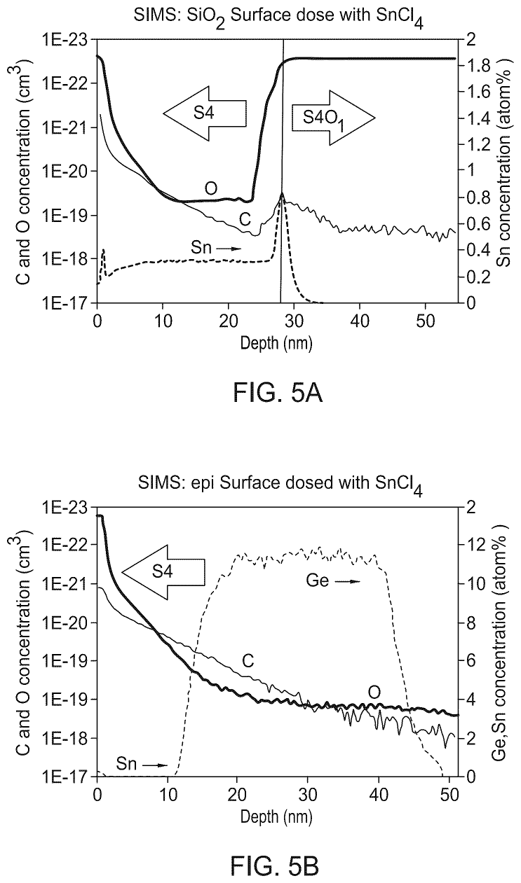

Tin was bound to the SiO₂ surface facilitating the inhibition, while no tin was found in the epitaxial material after the deposition, as shown in FIGS. 5A and 5B. Without being bound by theory, no detectable contamination of the conductive epitaxial material occurred.

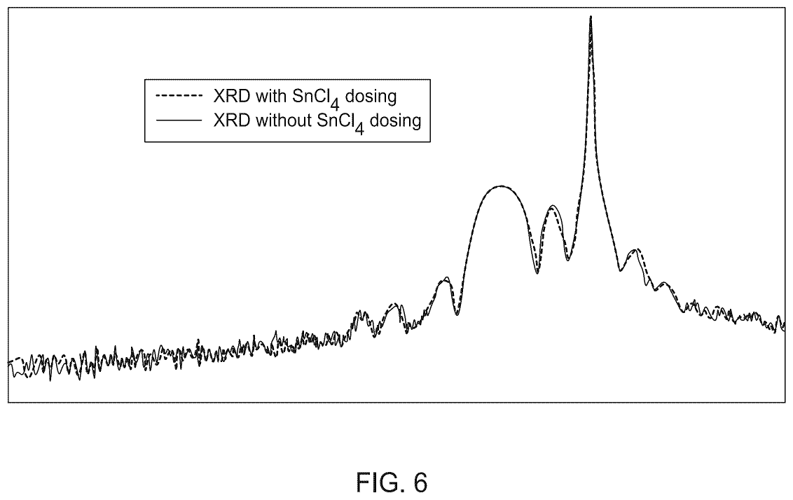

The crystal structure was obtained for both the reference substrate and the substrate treated with tin tetrachloride for 30 seconds prior to the selective epitaxial deposition process. The crystal structure was similar for both substrates, as shown in FIG. 6. Without being bound by theory, a similar crystal structure can indicate the growth rate of the epitaxial material for both substrates was the same.

### Example 2

A reference substrate was compared to a substrate that was treated with 35 sccm of tin tetrachloride or dichlorodimethylsilane for 30 seconds prior to the deposition of SiGeB. Each of the substrates were treated with 100 sccm SiH₄, 45 sccm GeH₄, and 10 sccm B₂H₆. A pressure of 10 Torr and a temperature of 550° C. was used. After the deposition, atomic force microscopy images of a central location and an edge of each of the substrates were generated. Nucleation density was determined by counting each discrete feature in the image and determining the density based on the scan area, e.g., 1 μm².

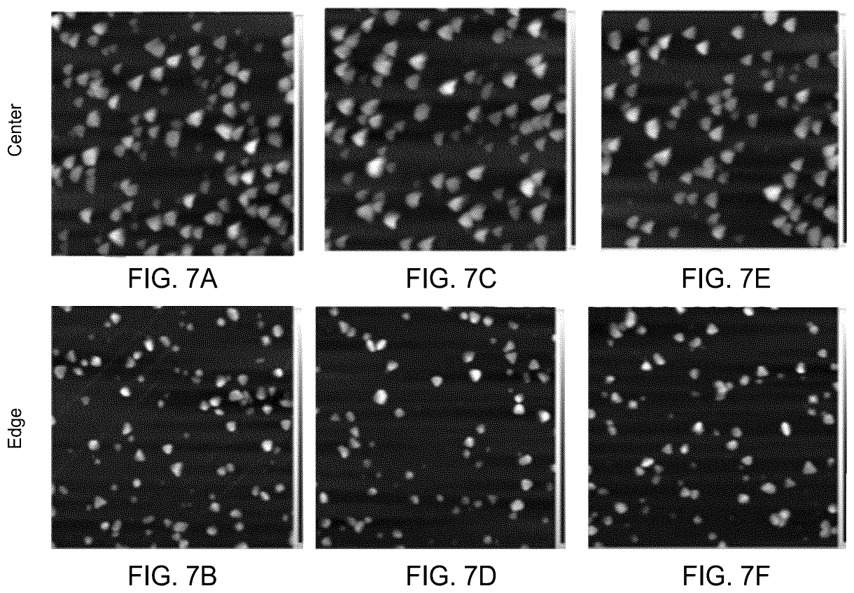

After the selective epitaxial deposition of SiGeB, the nucleation density of the reference substrate was 100 μm⁻² at the central location and 99 μm⁻² at the edge, as shown in FIGS. 7A and 7B. The substrate treated with tin tetrachloride for 30 seconds had a nucleation density of 76 μm⁻² at the central location and 75 μm⁻² at the edge, as shown in FIGS. 7C and 7D, indicating a nucleation density reduction of about 20% to about 30%. The substrate treated with dichlorodimethylsilane for 30 seconds had a nucleation density of 82 μm⁻² at the central location and 81 μm⁻² at the edge, as shown in FIGS. 7E and 7F. Without being bound by theory, a nucleation density reduction of about 20% to about 30% was obtained, improving a deposition selectivity window, thereby helping with process integration during manufacturing. Moreover, a reduction in the amount and size of nucleation points found on the surface, for both the center and edge, occurred, respectively.

### Example 3

Each of the substrates were treated with 100 sccm SiH₄, 45 sccm GeH₄, and 10 sccm B₂H₆. A pressure of 10 Torr and a temperature of 550° C. was used. After the deposition, atomic force miscopy images of each of the substrates was determined.

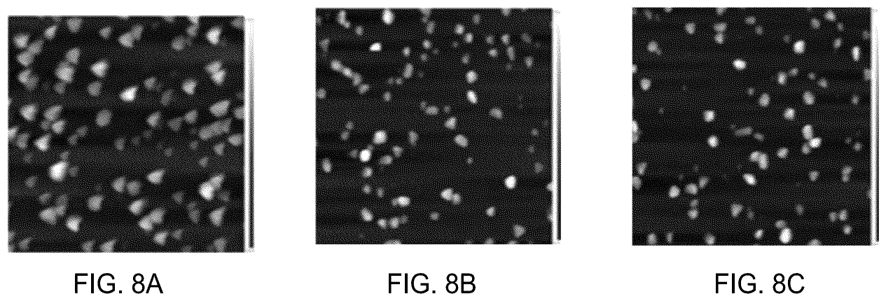

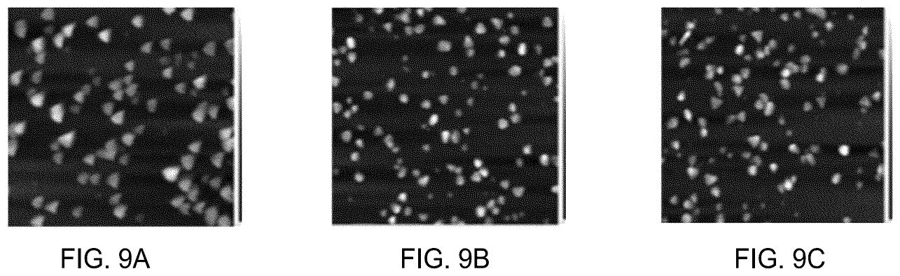

Flow rates of tin tetrachloride and dichlorodimethylsilane were varied to determine a nucleation density of SiGeB. A first substrate was treated with tin tetrachloride for 30 seconds at either 25 sccm, 35 sccm, or 45 sccm. The nucleation density was 76 μm⁻², 79 μm⁻², and 77 μm⁻² when operating at flow rates of 25 sccm, 35 sccm, and 45 sccm, respectively, as shown in FIGS. 8A-8C. The nucleation density remained similar across the varying flow rates. A second substrate was treated with dichlorodimethylsilane for 30 seconds at either 35 sccm, 45 sccm, or 55 sccm. The nucleation density was 82 μm⁻², 120 μm⁻², and 110 μm⁻² when operating at flow rates of 35 sccm, 45 sccm, and 55 sccm, respectively, as shown in FIGS. 9A-9C. The nucleation density increased with increasing flow rates of the dichlorodimethylsilane.

### Example 4

Each of the substrates were treated with 100 sccm SiH₄, 45 sccm GeH₄, and 10 sccm B₂H₆. A pressure of 10 Torr and a temperature of 550° C. was used. After the deposition, atomic force miscopy images of each of the substrates was determined.

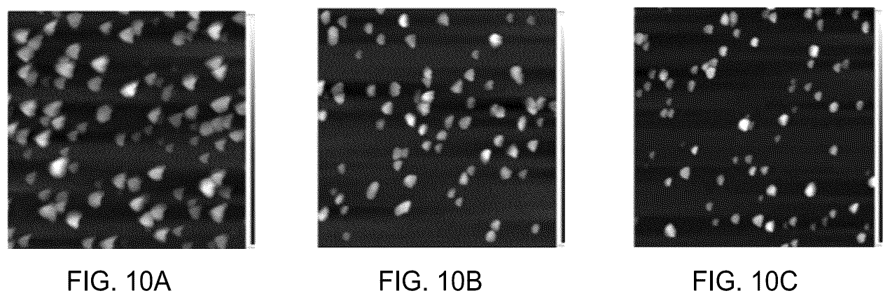

A substrate was treated with tin tetrachloride according to a cyclic pulsing method and a nucleation density of SiGeB was determined. A first substrate was pre-treated with tin tetrachloride as a single dose prior to exposure to a process gas, at a flow rate of 25 sccm, for 30 seconds. The nucleation density was 76 μm⁻², as shown in FIG. 10A. A second substrate was treated with tin tetrachloride, at a flow rate of 25 sccm, over two intervals, where each interval was 15 seconds. Process gases were introduced between the two intervals. The nucleation density was 67 μm⁻², as shown in FIG. 10B. A third substrate was treated with tin tetrachloride, at a flow rate of 25 sccm, over six intervals, where each interval was 5 seconds. Process gases were introduced between the intervals. The nucleation density was 69 μm⁻², as shown in FIG. 10C. Without being bound by theory, by administering the inhibitors as intervals the nucleation density was reduced, increasing device performance.

It is contemplated that one or more aspects disclosed herein may be combined. As an example, one or more aspects, features, components, operations and/or properties of the processing chamber 100; the controller 190; the substrate support 106; and/or the method 200 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated.

What is claimed is:

1. A method of processing a substrate, comprising:
exposing a surface of the substrate in a processing chamber to an inhibitor, wherein the surface of the substrate comprises one or more dielectric regions and one or more semiconductor regions, wherein the inhibitor comprises a halogen-containing compound comprising tin; and
epitaxially and selectively depositing a silicon-containing material layer on the substrate after exposing the surface of the substrate to the inhibitor.

2. The method of claim 1, wherein the halogen-containing compound is tin tetrachloride.

3. The method of claim 1, wherein the inhibitor is flowed into the processing chamber at a volumetric flow rate of about 1 standard cubic centimeters per minute (SCCM) to about 100 sccm.

4. The method of claim 3, wherein exposing the substrate to the inhibitor further comprises pulsing the inhibitor into the processing chamber for a period of time of about 0.1 seconds to about 60 seconds.

5. The method of claim 1, wherein the processing chamber has a pressure of about 1 Torr to about 300 Torr when flowing the inhibitor into the processing chamber.

6. The method of claim 1, wherein a temperature of the processing chamber is less than 550° C.

7. The method of claim 1, further comprising pre-cleaning the substrate.

8. A computer readable medium configured to:
expose a surface of a substrate in a processing chamber to an inhibitor, wherein the surface of the substrate comprises one or more dielectric regions and one or more semiconductor regions, wherein the inhibitor comprises a halogen-containing compound comprising one or more organic ligands; and
epitaxially and selectively deposit a silicon-containing material layer on the substrate after exposing the surface of the substrate to the inhibitor.

9. The computer readable medium of claim 8, wherein the one or more organic ligands are selected from the group consisting of C₁-C₆ alkyl, C₁-C₆ alkylene, C₁-C₆ alkynl, C₁-C₆ alkynlene, and a combination thereof.

10. The computer readable medium of claim 8, wherein the halogen-containing compound comprises a metalloid.

11. The computer readable medium of claim 10, wherein the metalloid comprises boron or silica.

12. The computer readable medium of claim 11, wherein the halogen-containing compound comprises dichlorodimethylsilane.

13. The computer readable medium of claim 8, wherein the inhibitor is flowed into the processing chamber at a volumetric flow rate of about 1 standard cubic centimeters per minute (sccm) to about 100 sccm.

14. The computer readable medium of claim 13, wherein exposing the substrate to the inhibitor further comprises pulsing the inhibitor into the processing chamber for a period of time of about 0.1 seconds to about 60 seconds.

15. The computer readable medium of claim 8, wherein the processing chamber has a pressure of about 1 Torr to about 300 Torr when flowing the inhibitor into the processing chamber.

16. The computer readable medium of claim 8, wherein a temperature of the processing chamber is less than 550° C.

17. A processing system, the processing system comprising:
a processing chamber; and
a controller, the controller configured to:
expose a surface of a substrate to an inhibitor to selectively inhibit growth of a dielectric material, wherein the inhibitor comprises tin tetrachloride or dichlorodimethylsilane, wherein the surface of the substrate comprises one or more dielectric regions and one or more semiconductor regions; and
epitaxially and selectively deposit a silicon-containing material layer on the substrate after exposing the surface of the substrate to the inhibitor.

18. The processing system of claim 17, wherein further comprising exposing the substrate to a plasma pre-cleaning process, wherein the plasma pre-cleaning process comprises a plasma clean process using NF₃ and NH₃.

19. The processing system of claim 17, wherein the inhibitor is flowed into the processing chamber at a volumetric flow rate of about 1 standard cubic centimeters per minute (SCCM) to about 100 sccm.

20. The processing system of claim 19, wherein exposing the substrate to the inhibitor further comprises pulsing the inhibitor into the processing chamber for a period of time of about 0.1 seconds to about 60 seconds.
